(19) United States
(12) Patent Application Publication
(10) Pub. No.: US 2007/0243703 A1
(43) Pub. Date: Oct. 18, 2007

(54) Processes and structures for epitaxial growth on laminate substrates

(75) Inventors: Thomas Pinnington, Pasadena, CA (US); Sean Olson, Santa Monica, CA (US); James M. Zahler, Pasadena, CA (US); Charles Tsai, Arcadia, CA (US)

Correspondence Address: FOLEY AND LARDNER LLP;SUITE 500, 3000 K STREET NW, WASHINGTON, DC, 20007, US

(73) Assignee: AONEX TECHNOLOLGIES, INC.

(21) Appl. No.: 11/785,038

(22) Filed: Apr. 13, 2007

Related U.S. Application Data
(60) Provisional application No. 60/791,896, filed on Apr. 14, 2006.

(51) Int. Cl. H01L 21/3205; H01L 21/28; H01L 21/4763

(52) U.S. Cl. 438/603; 438/604; 438/624; 438/688

(57) ABSTRACT

A method of making a semiconductor device includes providing a laminate substrate made by bonding a II-VI or III-V semiconductor laminate film to a support substrate, and preparing the laminate film to enable growth of a II-VI or III-V semiconductor device layer on the laminate substrate.

### CROSS-REFERENCE TO RELATED PATENT APPLICATIONS

The present application claims benefit of priority of U.S. provisional application Ser. No. 60/791,896, filed on Apr. 14, 2006, which is incorporated herein by reference in its entirety.

### FIELD OF THE INVENTION

The present invention relates to semiconductor devices and methods of making thereof.

### DESCRIPTION OF THE PRIOR ART

State-of-the-art photonic and electronic device structures are produced by deposition of crystalline thin films onto substrates which act as epitaxial templates for the deposited films. The optimization of such device structures is constrained by the physical properties of the available substrate materials. Relevant properties comprise the lattice mismatch and coefficient of thermal expansion (CTE) mismatch between the film and the substrate, and bulk substrate properties such as the thermal conductivity, electrical resistivity, optical absorption and reflection coefficients, dielectric function, radiation hardness, material density, and mechanical strength. Generally it is not possible to optimize all of the relevant properties using substrates of a single bulk composition, and in some cases suitable bulk substrates are not commercially available or are prohibitively expensive to produce. For example, Ge and InP substrates are respectively well lattice-matched to the GaAs and InGaAs films used in terrestrial and space-based photovoltaics; however the cost and weight of these substrate materials are relatively high compared to competing substrates such as silicon. Similarly GaN-based films are conventionally deposited on non-lattice-matched substrates such as sapphire or SiC, owing to the high cost of bulk GaN substrates; however defectively resulting from the high lattice mismatch and high CTE mismatch limits the performance of such substrates in the solid-state lighting or wireless communications markets.

### SUMMARY

An embodiment of the invention provides a method of making a semiconductor device, comprising providing a laminate substrate made by bonding a laminate film to a support substrate, providing a reactive etching species to the laminate substrate in the growth chamber or in a separate chamber; and epitaxially growing a semiconductor layer on the laminate film in the growth chamber. A Group V element overpressure may also be provided during the step of providing the reactive etching species.

Another embodiment of the invention provides a method of making a semiconductor device, comprising providing a laminate substrate made by bonding a III-V semiconductor laminate film to a support substrate; and annealing the laminate substrate while exposing the laminate film to a Group V element containing gas different from a Group V element of the laminate film.

Another embodiment of the invention provides a method of making a semiconductor device, comprising providing a laminate substrate made by bonding a sapphire laminate film to a support substrate; and annealing the laminate substrate while exposing the laminate film to a Group V element containing gas.

Another embodiment of the invention provides a method of making a semiconductor device, comprising providing a laminate substrate made by bonding a III-V laminate film to a support substrate; and annealing the laminate substrate while providing a mobile group III element to the laminate substrate.

Another embodiment of the invention provides a method of making a semiconductor device, comprising providing a laminate substrate made by bonding a laminate film to a support substrate; and diffusing a dopant into the laminate film.

Another embodiment of the invention provides a method of making a semiconductor device, comprising providing a laminate substrate made by bonding a laminate film to a support substrate; and forming an isolating structure selected from a p-n junction, a p-i-n junction or a super lattice of materials of differing band gaps, on the laminate film prior to epitaxially growing a device film over the isolating structure.

Another embodiment of the invention provides a method of making a semiconductor device, comprising providing a laminate substrate made by bonding a laminate film to a support substrate; epitaxially growing a graded interlayer on the laminate film; and epitaxially growing a buffer layer on the graded interlayer.

Another embodiment of the invention provides a semiconductor device, comprising a laminate substrate made by bonding a laminate film to a support substrate; an epitaxially grown graded interlayer located on the laminate film; and an epitaxially grown a buffer layer located on the graded interlayer.

Another embodiment of the invention provides a method of making a semiconductor device, comprising providing a laminate substrate made by bonding a laminate film to a support substrate; and epitaxially growing an interlayer on the laminate film, such that a growth temperature of the interlayer is increased during growth of the interlayer.

Another embodiment of the invention provides a semiconductor device, comprising a laminate substrate made by bonding a laminate film to a support substrate; a mask having an opening located on the laminate film; and a SAG grown epitaxial buffer layer which contacts the laminate film through at least one opening in the mask.

Another embodiment of the invention provides a semiconductor device, comprising a laminate substrate made by bonding a laminate film to a support substrate; a superlattice comprising layers having different mechanical properties located over the laminate film; and an epitaxial buffer or device layer located over the superlattice.

Another embodiment of the invention provides a method of making a semiconductor device, comprising providing a laminate substrate made by bonding a laminate film to a substantially metallic support substrate; epitaxially growing a III-nitride layer on the laminate film; and adjusting a resistive heater power or an RF induction heater power during the step of epitaxially growing to account for a reflectivity and/or a magnetic susceptibility of the support substrate.

Another embodiment of the invention provides a method of making a semiconductor device, comprising providing a laminate substrate made by bonding a laminate film to a reflective support substrate; epitaxially growing a III-nitride layer on the laminate film, wherein the laminate film is substantially optically transparent; and using optical in-situ monitoring techniques during the step of epitaxial growth by utilizing a reflectivity of the support substrate.

Another embodiment of the invention provides a method of making a semiconductor device, comprising providing a laminate substrate made by bonding a sapphire laminate film to a support substrate; and annealing the laminate substrate while exposing the laminate film to a Group III element containing gas.

### DESCRIPTION OF THE DRAWING

FIG. 1 is a side cross sectional view of a graded interlayer structure for mitigating the effects of CTE mismatch. The structure comprises a support substrate 1, a bonding layer 2, a laminate layer 3, a graded interlayer 4, and an epitaxial buffer layer and device structure 5. The composition of the graded interlayer 4 is such that the composition at the bottom most portion 6 differs from the composition at the top most portion 7, and the composition between the portions 6 and 7 is graded either continuously or in discrete steps.

### DETAILED DESCRIPTION OF EMBODIMENTS OF THE INVENTION

Laminate substrates offer significant performance and cost advantages over traditional bulk substrates. Laminate substrates comprise a thin crystalline film attached to an underlying support substrate (which is also referred to as a handle substrate), which itself may be crystalline, polycrystalline, amorphous, or formed from a composite material. Intermediate layers between the crystalline film and the support substrate may also be included to facilitate the adhesion of the film to the support substrate.

For example, an InP film attached to a crystalline silicon substrate is a low-cost, light-weight alternative to bulk InP. Similarly a thin sapphire film bonded to a pressed and sintered molybdenum substrate material, is a low-cost, high thermal conductivity, and CTE-matched substrate for GaN growth. Specific examples of laminate substrate combinations and manufacturing processes can be found in U.S. provisional application Ser. No. 60/762,490 filed on Jan. 27, 2006 and U.S. application Ser. Nos. 11/255,194 and 11/357,436, filed on Oct. 21, 2005 and Feb. 21, 2006, respectively, all incorporated herein by reference in their entirety.

Epitaxial growth of a thin film on a laminate substrate presents specific opportunities for the optimization of the growth process and the growth structure. Accommodation should be made for the difference in thermal conductivity, emissivity, and the RF and radiative absorption coefficients of the laminate substrate compared with a traditional bulk substrate. In some cases, properties such as the emissivity can change as growth proceeds. In addition, the difference in CTE between the laminate film and the underlying support substrate can produce strain in the laminate film at the growth temperature. Since the laminate film forms the epitaxial template for subsequent film growth, the deposited film will generally also be strained.

Transition layers can be inserted into the growth structure in order to minimize wafer bow or to minimize the propagation of strain-relieving defects into the active layers of the device structure. Opportunities also arise during pre-growth processing of the substrates or during the initial growth steps to enhance the performance of the laminate film itself by modification of its dopant level or dopant type, reduction of its defectively, or modification of its surface morphology.

The embodiments of the invention provide improved processes and structures relating to the growth of crystalline films on laminate substrates. The growth can be performed using any number of techniques known in the art, including chemical vapor deposition (CVD) and metalorganic chemical vapor deposition (MOCVD), molecular beam epitaxy (MBE), hydride vapor phase epitaxy (HVPE) and Ion Beam Assisted Deposition (IBAD).

Note that the processes and structures described herein are intended to represent examples of the more general concepts disclosed and are not intended to limit the scope of this invention. The processes and structures described herein are relevant to multiple areas of compound semiconductor manufacturing comprising light emitting diodes (LEDs), laser diodes (LDs), RF power amplifiers, photodetectors, optoelectronics, and integrated logic/compound semiconductor devices.

### 1. Processes and Structures Relating to the Modification of the Laminate Film Properties

Laminate films are typically attached to the support substrate using wafer bonding and layer transfer techniques known in the art. In some cases the resulting laminate film as it is supplied prior to growth, will not be optimally conditioned for high quality epitaxial growth, or specific material properties of the laminate film as they relate to the operation of the device structure will be non-optimal. If the layer transfer has been achieved using an ion-implantation process for example, the implantation damage can produce a high density of point defects in the laminate film, and can also affect the density of activated dopant species within the film. Furthermore the surface of the as-transferred film will in general be rough, due to the stochastic nature of the implantation and layer detachment process. Therefore it will generally be advantageous to perform additional processing steps either prior to growth or during the growth process, or to insert additional layers into the growth structure, in order to optimize the growth process or to optimize the performance of the laminate film within the final device structure.

### 1.1 Reduction of Surface Roughness

In order to reduce the surface roughness of the laminate substrate prior to growth, an annealing procedure can be used to enhance the thermally activated diffusion of surface species, resulting in a smoother surface. For a laminate film material the degree of smoothing is largely controlled by the temperature and the duration of the annealing process. Optionally an overpressure of precursor species can be supplied to the surface during annealing. The specific process parameters such as pressure, temperature, precursor flow rate or molecular flux, must be optimized for each laminate material composition and growth technique.

Smoothing of the laminate substrate roughness can also be accomplished by growth of a buffer layer consisting of a thin film of material that is substantially lattice-matched to the laminate film. The buffer layer can comprise a single layer of a single composition, or it can comprise multiple layers of various compositions, for example it may comprise a super lattice of alternating layers of AlGaAs and GaAs for the case of growth on a GaAs template, or InAlAs and InGaAs for the case of growth on an InP template layer. Alternatively the roughness and residual damage in the laminate film can be removed using an in-situ etching process, wherein a reactive or etching species, such as HCl, CBr₄ or other suitable compounds, such as halide compounds which can etch the film being deposited on the laminate substrate during growth is introduced into the growth chamber during the growth of the film.

### 1.1.1 Pre-Growth Annealing of Compound Laminate Films Under Group-V or Group-VI Overpressure

During annealing of a laminate film comprised of a III-V or II-VI compound semiconductor material, where the annealing temperature is near or above the congruent sublimation point of the compound semiconductor material, it will be advantageous to supply an overpressure of either the group-V or group-VI elements respectively, in order to suppress the decomposition of the surface. As is known in the art, these elements can be supplied by a precursor gas such as arsine (AsH₃), tertiary butyl arsine (TBA), phosphine (PH₃), tertiary butyl phosphine (TBP), hydrogen selenide, and ammonia (NH₃) in the case of MOCVD, HVPE or gas-source MBE, or as molecular or elemental species such as As₂, P₂, or atomic-N in the case of solid source MBE. The optimal flow rate of the precursor species will depend on both the vapor pressure of the group-V or group-VI constituent evaporating from the laminate film, which will increase with temperature, and on the dissociation of the precursor species in the gas phase or at the surface of the substrate, which occurs more efficiently at higher temperature. Thus, the laminate film is annealed after being transferred to the support substrate but prior to growth of epitaxial layer(s) on the laminate film.

If the laminate film is a III-V material comprising InP or GaAs, precursors for P or As can be supplied to preserve the surface against decomposition if the annealing temperature is near or above 360° C. or 580° C. respectively for InP or GaAs. The annealing can also be performed using a group-V precursor that does not correspond to the group-V constituent of the laminate film, but in this case the composition of the laminate film surface will be altered through exchange of the group-V elements. For example if the laminate film is composed of GaAs and a precursor for P is supplied during the annealing process, the surface composition of the laminate film will be changed to GaAsP or GaP. If the laminate film is comprised of a compound containing more than one group-V element, such as InGaAsP or InAlAsP, the surface can be preserved during annealing using a combination of the group-V precursors, such as AsH₃ and PH₃. In this case the relative proportion of the As to P precursor required to maintain the surface composition will depend on the relative vapor pressures of the constituent group-V elements at the annealing temperature, and the relative dissociation efficiencies of the precursors.

The operating parameters for MOCVD growth systems are typically optimized for growth uniformity and quality. In general, the operating parameters for the pre-growth annealing procedure will be optimized differently in order to maximize the effectiveness of the annealing procedure in reducing the surface roughness of the laminate film. For example, it has been shown (Park, 2003) that a reduction in the flow rate of the carrier gas (typically hydrogen) that controls the gas flow dynamics in the MOCVD reactor, can lead to a significant improvement in the degree of smoothing of a textured InP surface during annealing. It is anticipated that a similar improvement can be made in the smoothing of a laminate film surface using this technique, and other techniques developed for the planarization of textured surfaces. Thus, the group V or group VI containing gases are transported to the growth chamber by means of a carrier gas such as nitrogen or hydrogen, and the carrier gas flow rate during the annealing process is less than the flow rate during the subsequent growth of the device structure.

### 1.1.2 Use of Highly Mobile Group-III Species During Pre-Growth Annealing or Buffer Layer Growth

As is known in the art, the mobility of the different group-III elements during growth of a III-V film depends on the growth temperature and pressure and varies substantially among elements. In the case of MOCVD growth, the mobility derives from a combination of gas phase diffusion of the precursor species and surface diffusion of the adsorbed atomic species. In MBE growth, the mobility is controlled by surface diffusion processes.

Of the group-III elements used in the production of III-V films, indium is known to have a higher mobility than Ga or Al. Because of its higher mobility, indium can be used to facilitate enhanced smoothing of surfaces during buffer layer growth. For example it has been shown (Mullan, 1997) that textured InP surfaces planarize more quickly during buffer layer growth by MOCVD as the In-content of the lattice-matched buffer layer film (InP, InGaAsP, or InGaAs) is increased. Similarly it has been shown (Lavoie, 1996) that the smoothing of a rough GaAs surface during growth of a GaAs buffer layer by MBE, is accomplished much more rapidly if a flux of indium atoms is supplied during the growth and the temperature is high enough that the indium atoms do not incorporate significantly into the film. Accordingly it is believed that the effectiveness of either a buffer layer growth process or a pre-growth annealing process can be improved if indium or one of its precursor species such as trimethyl indium is introduced into the growth or annealing chamber during the buffer layer growth and/or pre-growth annealing process. In the case of buffer layer growth at a sufficiently low temperature that indium is incorporated into the film, the smoothing is enhanced due to the longer diffusion length of the indium relative to other group-III species. Preferably for the case of an In-containing buffer layer, the growth temperature is between 450 C and 600 C in the case of growth by MBE, and between 550 C and 700 C for the case of growth by MOCVD. In the case of buffer layer growth or annealing at a temperature high enough that indium is not incorporated into the film, the smoothing is enhanced by a surfactant effect of the indium atoms which segregate at the surface, in which the effective diffusion length of the constituent group-III atoms (Ga and/or Al) in the (Ga and/or Al)—(Group V) film is increased. Preferably for the case of buffer layer growth or the case of annealing that does not incorporate significant indium into the film, the growth or annealing temperature is between 550 C and 650 C for growth or annealing in an MBE growth chamber, and between 650 C and 750 C for growth or annealing in an MOCVD growth chamber. The buffer layer may comprise an (In, Al and/or Ga)-(Group V) binary, ternary or quaternary layer, where the ternary or quaternary material may comprise more than one element from Group III and/or Group V.

### 1.2 Pre-Growth Damage Removal and Cleaning

The layer transfer process used to fabricate the laminate substrate typically relies on ion-implantation-induced exfoliation or some other mechanical shearing technique, in order to separate a laminate film from the donor substrate. The portion of the laminate film nearest the surface of the resulting laminate substrate is generally highly defective as a result of this separation process. In many cases a polish process can be used to remove this damage. In some cases it may be beneficial to perform part or all of the damage removal process immediately prior to growth, after the laminate substrate has been loaded into the growth reactor. In other cases it may be advantageous to perform an in-situ cleaning process to remove impurities such as oxygen from the laminate film surface. As is known in the art, in-situ etching and cleaning of the semiconductor substrate surfaces can be accomplished by exposure of the surface to reactive gases. Typically these gases contain either Cl or Br and include HCl, Cl₂, CCl₄, CBr₄, CH₃Cl, PCl₃, tertiarybutylchloride (TBCI) and tertiarybutylbromide (TBBr), CH₃C₁, C₂H₅Br, and C₂H₅Cl (Franke, 2003). Etching and cleaning with H₂, atomic hydrogen, or hydrogen radicals is also possible. Generally it is also necessary to heat the semiconductor substrate in order to promote the dissociation of the reactive gas and accelerate the etching of the semiconductor material. During the heating of III-V materials, it is also advantageous to supply an overpressure of the group-V species in order to preserve the surface stoichiometry. It is believed that introduction of a reactive gas into the growth chamber, and exposure of said gas to a suitably heated laminate substrate, is effective for removing impurities from the laminate substrate surface, and removing the damaged material near the surface of the laminate film. In general the amount of material etched will increase with substrate temperature, flow rate of the reactive gas, and with exposure time. Preferably the exposure time is between 1 minute and 120 minutes.

Etching and cleaning of a GaAs laminate film, attached for example to a silicon support substrate, can be accomplished in an MOCVD growth system by heating the laminate substrate to a temperature between 300 C and 800 C and exposing the surface to a flow of HCl or other reactive gas. Preferably a flow of AsH₃ or TBA is supplied in order to preserve the stoichiometry of the surface. The introduction of AsH₃ during the etching procedure can also promote the removal of oxygen contamination at the surface (Mochizuki, 2004). Optionally a flow of trimethyl gallium (TMG) or other precursor for Ga can be supplied. This will reduce the effective etch rate and could also improve the removal of silicon contamination from the surface (Mochizuki, 2004). In an MBE growth system, cleaning and etching of the GaAs laminate film can be achieved using atomic hydrogen or hydrogen radicals, or using Cl₂ or other reactive gas.

Etching and cleaning of an InP laminate film attached to a silicon, GaAs, or other support substrate, can be accomplished in an MOCVD growth system by heating the substrate to a temperature between 200 C and 700 C and exposing the surface to a flow of any of a number of reactive gases including PCl₃, TBCI, TBBr, CBr4 or CCl₄. Preferably the substrate temperature is greater than 500 C to promote a smoother surface. A flow of PH₃ or TBP can be advantageously supplied to preserve the surface stoichiometry. Optionally trimethyl indium or other precursor for indium can also be supplied.

Etching and cleaning of a laminate film of Al₂O₃ or sapphire attached to a substrate comprised of poly-crystal AlN, molybdenum, molybdenum alloy, silicon, or other material, can be accomplished prior to growth of GaN, AlN or other III—nitride alloy, by heating the substrate to a temperature between 400 C and 1300 C, and exposing the surface to a flow of H₂, HCl or other reactive gas. Optionally NH₃ can be supplied to nitridize the surface, or trimethyl gallium (TMG) or other gallium precursor can be supplied to control the polarity of the subsequent growth. In some cases it will be advantageous to supply these gases after the reactive etching gas supply has been terminated. It has been shown (Grzegorczyk, 2005) that exposure of a Al₂O₃ surface to TMG for extended periods (up to 120 minutes) prior to deposition of GaN, can promote the growth of Ga-polarity GaN. It is expected that exposure of a laminate Al₂O₃ film to TMG, trimethyl aluminum, or trimethyl indium, can be used to promote the growth of group-III polarity GaN, AlN, or InN.

An epitaxial layer, such as an epitaxial III-V semiconductor layer is grown on the laminate film subsequent to the etching and/or cleaning process. Preferably the laminate film is not exposed to room air or other contaminating environments following the etching and/or cleaning process and prior to growth. More preferably the growth is conducted without breaking vacuum, between the etching and/or cleaning and growth. Optionally, the growth is conducted in the same chamber in which the etching and/or cleaning process is performed. However, the growth may be conducted in a separate chamber, such as in a growth chamber of a multi-chamber apparatus, in which the growth chamber is separate from one or more cleaning and/or etching chambers.

### 1.3 Modification of the Composition of the Laminate Film Surface

In some cases it will be advantageous to alter the material composition of the laminate film surface region. For example the quality of the subsequent epitaxial growth may be improved by reducing strain that has developed in the laminate film due to its CTE mismatch with the support substrate. In the case of a single crystal laminate film comprised of a compound material such as InP, GaAs, or Al₂O₃ (sapphire), the surface composition can be modified through exposure of the surface during annealing to a precursor gas of a group-V element that differs from any of the elements of which the laminate film is comprised. The degree to which the film composition is transformed will increase as the temperature of the substrate and the duration of the annealing process is increased.

If the laminate film is InP, exposure at elevated temperature to an As precursor gas such as AsH₃ or TBA in and MOCVD reactor, will result in the transformation of a thin surface layer of the laminate film from InP to InAsP or InAs. Preferably the annealing temperature is between 300 C and 700 C and the duration of the anneal is between 1 minute and 10 minutes. This process will cause the strain state of the laminate film to become more compressive. For example if a support substrate having a higher CTE than InP is used, such as GaAs, then this process will reduce the tensile strain that has developed in the laminate film as it was heated to the annealing temperature and/or will increase the compressive stress in the film surface.

If the laminate film is Al₂O₃, an annealing process can be performed in NH₃ to nitridize the surface, as is known in the art for growth of GaN on bulk Al₂O₃ substrates. Alternatively, the substrate can be exposed to a precursor for one of the group-III elements such as TMAI, TMGa, or TMIn during the annealing process, in order to promote group-III polarity growth of the subsequent nitride film.

### 1.4 Modification of Electrical Properties of the Laminate Film

The electrical properties of a laminate film are determined both by the electrical properties of the donor substrate from which the laminate film was obtained, and by changes in the electrical properties resulting from the layer transfer processes, such as ion implantation. It will often be the case that the electrical properties of the laminate film will not be suitable for optimal device performance. Accordingly processes can be implemented before or during the growth process to modify the electrical properties of the laminate film, or layers can be inserted into the growth structure that shield the device from the non-optimal laminate layer.

### 1.4.1 Diffusion of Dopant Species

If the laminate film does not contain a sufficient concentration of activated electrical dopants, or if the net dopant concentration is of the opposite type of what is optimal for the device performance, additional dopants of a specified type can be added to the laminate film using diffusion techniques. The dopant is selected to be one of Zn, Si, Se, Mg, Fe or any of a number of dopants selected for their doping type and diffusivity. The laminate substrate is heated to a temperature between room temperature and a temperature less than 200 C higher than the usual growth temperature for the material, but preferably within 100 C of the growth temperature, in order to promote the diffusion of the dopant species into the laminate film. The dopant is supplied either as an atomic flux in the case of MBE or as a metalorganic or hydride precursor in the case of MOCVD. Suitable precursors are dimethyl zinc, trimethyl zinc, hydrogen selenide, silane, disilane, ferrocene, or any of a number of chemical compounds as is known in the art. The final concentration of the dopant in the laminate film, and the depth to Which the dopant concentration persists in the film, will depend on the temperature at which the diffusion is performed, the duration of the diffusion process, and the solubility of the dopant within the laminate film material. In the case of diffusion of dopants into a III-V laminate film at elevated temperature, it will be advantageous to supply a flow of group-V precursor gas during the diffusion process.

If the laminate film is comprised of InP or GaAs, and the desired dopant type is p-type, then a suitable dopant species for the diffusion process is zinc. Dimethyl zinc or trimethyl zinc or other precursor can be used. A flow of PH₃ or TBP, or of AsH₃ or TBA can be supplied to stabilize the material composition of an InP or GaAs film, respectively. Preferably the substrate is heated to a temperature between 300 C and 700 C for the case of InP, and between 300 C and 800 C for the case of GaAs. The duration of the diffusion process is preferably between 5 minutes and 60 minutes.

It is further possible to promote diffusion of dopant species into the laminate film by growth of a doped layer adjacent to the transferred layer. Diffusion is accomplished either at the growth temperature of the layer or subsequent layers during the growth, or by a post growth heat treatment. If the laminate film is comprised of InP, and the desired dopant is p-type, then a Zn-doped layer of a material substantially lattice-matched with InP, for example InP, InGaAs, or InAlGaAs, can be grown immediately adjacent the transferred layer, at a temperature between 400 C and 700 C. The degree of diffusion will in general be less if the grown film contains a high concentration of Al, for example InAlAs is known to be effective at blocking the diffusion of Zn. In other words, after the transferred layer is transferred from a donor substrate to the support substrate, a doped diffusion source layer is grown on the transferred layer. Annealing causes the dopant to diffuse from the diffusion layer into the transferred layer. The diffusion layer and the transferred layer together comprise the laminate film. The dopant can render the semiconducting laminate film p-type, n-type or semi-insulating.

### 1.4.2 Growth of an Electrically Isolating Structure

Defects within the laminate film, or at the interface of the laminate film and the adjacent epitaxial film, can modify the electrical properties within the epitaxial film and affect the final device performance. For example the Fermi level may become pinned at the interface or within the defective laminate film, resulting in an electric field of about 1×10⁴ to 1×10⁵ V/cm, which can extend one micron or further into the epitaxial film. One way to shield the device from the effects of this electric field is to grow a buffer layer that is thicker than the spatial extent of the electric field. It has been shown (Chang, 2001) that the required thickness of such a buffer layer can be substantially reduced by inserting a superlattice, a p-n junction or a p-i-n junction into the buffer layer growth, to enhance the screening of the electric field. It is believed these structures can be used to isolate the device structure from the electrical effects of the defects in the laminate film or at the interface between the laminate film and the epitaxial device layer. In other words, a superlattice, a p-i-n junction or a p-n junction are provided between the laminate film and a device layer.

If a superlattice structure is used to facilitate electrical screening as described above, the structure preferably consists of alternating layers of material having substantially differing energy band gaps, wherein the thickness of each layer is between 5 nm and 50 nm, and the total number of layers is between 5 and 50. Optionally the layers can be doped to facilitate electrical conductivity in the device structure. If the laminate film is GaAs, the alternating layers are preferably composed of AlAs and GaAs, or AlGaAs and GaAs. If the laminate film is InP, a suitable superlattice structure would consist of alternating layers of InAlAs and InGaAs, or InAlAs and InP, or InGaAs and InP.

If the electrical screening is accomplished using a p-n or a p-i-n junction, the structure consists of two or three distinct layers, respectively, with differing dopant types as is known in the art. The thickness of each layer is preferably between 10 nm and 100 nm, and the dopant concentration in the p and n-type layers is between 3×10¹⁷/cm³ and 3×10¹⁹/cm³. The material composition of the distinct layers can be chosen to be the same, or layers of differing material composition can be used. For example, if the laminate film is InP, a p-i-n junction can be grown consisting of n-type InP, undoped InAlAs, and p-type InGaAs, all substantially lattice-matched to InP.

Optionally the buffer layer is designed to be semi-insulating by incorporation of appropriate dopant species during the growth, as is known in the art. For the case of an InP or GaAs semi-insulating buffer layer, Fe or Cr respectively may be used as dopant species. Preferably the thickness of the buffer layer is chosen to be between 200 nm and 2000 nm thick.

### 2. Structures and Processes that Minimize Defects Associated with CTE Mismatch

In general the CTE of the support substrate on which the laminate film is attached will not match the CTE of the laminate film. There can also be a CTE mismatch between the support substrate and the epitaxial layers that are deposited on the laminate film. This CTE mismatch can result in strain in the laminate film and in the deposited epitaxial layers. Strain can develop at different stages of the growth process. Prior to deposition of the epitaxial layers, CTE mismatch strain can develop when the laminate substrate is heated to either the pregrowth-annealing temperature or the growth temperature. During growth, CTE mismatch can change the strain state of the laminate film and the deposited layers, when the temperature is cycled to different values. Such temperature cycling is commonly used in epitaxial growth in order to optimize the properties of different layers. For example, a nucleation layer, buffer layer, a multiple quantum well layer, and a highly doped capping layer are typically all grown at different temperatures. Finally, CTE mismatch between the grown layers and the support substrate can result in substantial strain in the grown layers when the substrate is cooled to room temperature following growth. Post growth thermal processing such as occurs during laser lift off, heat sink attachment, and contact alloying will induce further changes in the strain state of the grown layers.

A variety of structures and processes have been developed to mitigate the effects of strain between layers of lattice-mismatched and CTE-mismatched materials. Examples include growth of linearly-graded interlayers (Hsuch, 2003), step-graded interlayers (Zeng, 2001), superlattice structures (Shimizu, 2004), and selective area growth (Yamaguchi, 1990). It is expected that any of these structures and processes, and others not mentioned here, that have been developed to reduce the stress or the defects associated with strain relief in layers of differing lattice constant or CTE, can be advantageously applied to the growth of epitaxial films on laminate substrates.

### 2.1 Graded Interlayers

Compositionally graded interlayers can be effective at reducing the stress at interfaces between strained layers (Hsuch, 2003). The equilibrium lattice constant of the interlayer material at the start of the interlayer growth is typically selected to substantially match the equilibrium lattice constant of the underlying layer on which the interlayer is deposited, and the equilibrium lattice constant at the end of the interlayer growth is selected to substantially match the equilibrium lattice constant of the material that will be deposited on the interlayer. The interlayer composition can be graded linearly or in some other continuous manner, or in a discontinuous stepwise manner. Such graded layers can be used to reduce the CTE-mismatch stress as can occur during growth on laminate substrates.

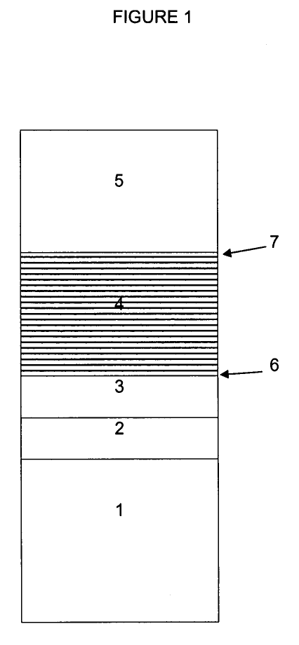

A structure comprising a support substrate, a bonding layer, a laminate film, a graded interlayer and an epitaxial buffer layer and device structure, is shown in FIG. 1. For the case of a laminate substrate comprising an InP laminate film 3 attached to a Si support substrate 1, the compositionally graded layer 4 can be an alloy comprising InGaAs, InAlAs, InAlGaAs or InGaAsP. Preferably the graded layer material is comprised of InAlAs or InGaAs. If maximum optical transparency is required, for example if it is desired to use the silicon support substrate material as a junction in a multi-junction solar cell, then it is more preferable that the graded layer material be comprised of InAlAs. The exact compositions at the start 6 and end 7 of the graded interlayer growth are selected to minimize the strain-induced defects in the device structure, and will depend on the temperature at which the InP film was bonded to the Si substrate, the temperature at which growth occurs, and the composition of the device layer to be deposited adjacent to the interlayer. If the temperature at which the InP film was bonded to the Si substrate is between 25 C and 75 C, then the starting composition of the interlayer is preferably selected to correspond to the range 51.0%<x<51.6% or 50.0%<y<50.6% for alloys of In(x)Ga(1−x)As or In(y)Al(1−y)As respectively. If the bonding was performed at a temperature between 200 C and 250 C, then the starting composition of the interlayer is preferably in the range of 51.4%<x<52.1% or 50.4%<y<51.1% for alloys of In(x)Ga(1−x)As or In(y)Al(1−y)As respectively. If the composition of the device layer to be grown adjacent to the graded interlayer is such that its equilibrium lattice constant is substantially lattice-matched to InP at the growth temperature, and if the growth temperature is between 550 C and 650 C, then the final composition of the interlayer is preferably in the range of 51.9%<x<52.6% or 50.9%<y<51.6% for alloys of In(x)Ga(1−x)As or In(y)Al(1−y)As respectively. More preferably for the case of an In(x)Ga(1−x)As or In(y)Al(1−y)As interlayer, the concentration of indium or aluminum respectively at the topmost portion 7 of the interlayer is between 1.6% and 2.4% higher than the concentration of indium or aluminum at the bottom most portion 6 of the interlayer, if the temperature at which the InP film was bonded to the Si substrate is between 25 C and 75 C, and between 0.6% and 1.4% higher if the bonding temperature is between 200 C and 250 C. The thickness of the graded interlayer is preferably between 0.1 microns and 2 microns. For the case of growth using MOCVD, the temperature of the graded interlayer growth is preferably between 450 C and 600 C for an interlayer comprising In(x)Ga(1−x)As and preferably between 600 C and 700 C for an interlayer comprising In(y)Al(1−y)As.

Alternatively, the material composition of the interlayer can be kept substantially constant and the temperature of the interlayer growth can be increased continuously or in a stepwise manner throughout the growth. In such temperature-graded interlayer growth, the temperature at the start of the growth is selected to be below the final growth temperature of the device layers, and the final temperature of the interlayer growth is chosen to be substantially the same as the temperature of the device layer growth (i.e., 10% or less, such as 5% or less difference between the device layer growth and final interlayer growth temperatures). Preferably the temperature at the start of growth is between 300 C and a temperature at least 200 C below the device layer growth temperature.

### 2.2 Other Structures

Selective area growth (SAG) mask structures can be used to reduce film stress as can occur due to CTE mismatch effects (Yamaguchi, 1990). For the case of a GaAs or InP layer attached to a silicon or other suitable support substrate, a silicon dioxide or silicon nitride or other insulating layer growth mask can be applied to the surface prior to growth using PECVD or other deposition techniques and photolithographic patterning as is known in the art. Preferably the thickness of the growth mask is between 50 nm and 1000 nm, the width or diameter of the mask features is between 2 microns and 20 microns, and the spacing between the mask features is between 5 microns and 100 microns. As is known in the art, the pressure, temperature and growth rate of the growth over the mask structure are optimized in order to promote crystalline growth between the mask features and lateral overgrowth over the mask features. In other words, a plurality of mask features are formed on the laminate film leaving a portion of the film exposed. The buffer layer epitaxially grows on the exposed film portions and laterally overgrows the masking features.

Superlattice structures consisting of alternating layers of materials having differing mechanical properties can be inserted into the growth structure to encourage bending of threading dislocations into the interfaces between the superlattice layers (Shimizu, 2004). Such threading dislocations can occur due to CTE-mismatch strain between the deposited film and the laminate substrate. These superlattice structures can be used to reduce the number of threading dislocations reaching the device layers and thereby improve the performance of the device film in the final device. For the case of GaAs template layer attached to a silicon support substrate, the superlattice preferably comprises alternating layers of Al(x)Ga(1−x)As and GaAs, with 0.1<x<0.5, each layer is between 10 nm and 300 nm thick, and the total number of layers is between 3 and 30. Preferably, the superlattice structure is located between the laminate film and the buffer or device layer.

### 3. Structures and Processes Relating to III-Nitride Growth on Non-Lattice-Matched Laminate Substrates

Due to the lack of low-cost, commercially available bulk substrates of III-nitride material, the growth of III-nitrides such as GaN, InGaN, AlGaN, and AlN is commonly performed on substrates which differ greatly in lattice constant (typically by between 2% and 20%) with the device layer lattice constant. A variety of strategies have been developed to enable the growth of III-nitride films on such lattice-mismatched substrates, including lateral epitaxial overgrowth and pendeo-epitaxy (Zheleva, 1999), maskless pendeo-epitaxy (Einfeldt, 2002), and growth of a thin low-temperature AlN or GaN buffer layer (Zhang, 2004). Generally the CTE of the substrate also differs substantially from the CTE of the III-nitride device layer. Accordingly it is advantageous to use a laminate substrate comprising a layer of the lattice-mismatched material, attached to a support substrate that is substantially CTE-matched with the III-nitride device layer (i.e., the CTE difference is 10% or less). Examples of such a laminate substrate comprise a layer of c-axis single-crystalline sapphire or SiC, or (111) silicon, attached to a support substrate comprised of polycrystalline AlN or a substantially metallic substrate, such as a molybdenum, or a pressed and sintered alloy of molybdenum and/or tungsten, for example a titanium and zirconium containing alloy of molybdenum which is commercially referred to as TZM. The support substrate is substantially thicker than the laminate film, such as 100 to 2000 times thicker, and provides the CTE match of the overall laminate substrate to the III-nitride layer.

The techniques developed for growth of III-nitrides on lattice-mismatched substrates can be advantageously applied to III-nitride growth on laminate substrates comprising a layer of lattice-mismatched material (i.e., the laminate film) on a CTE-matched support substrate. Owing to the reduction in CTE mismatch, many of these techniques can be employed to greater advantage on laminate substrates. For example, coalescence defects observed on pendeo-epitaxy grown material have been linked to CTE mismatch effects associated with thermal cycling during the selected area growth process. Such coalescence defects can be reduced in material grown on CTE-matched laminate substrates. Additionally, substrate bowing and/or film cracking and dislocation formation is commonly observed in growth of III-nitride device layers, and has been linked to CTE-mismatch stress induced after growth during cooling of the substrate to room temperature. Such bowing, cracking and/or dislocation formation can be substantially reduced or eliminated through the use of CTE-matched laminate substrates.

In the growth of GaN on sapphire or other lattice-mismatched substrates, bow associated with tensile stress can develop during growth of the high-temperature GaN layer that is deposited adjacent to the thin, low-temperature AlN or GaN buffer layer. As is known in the art, it is possible in the case of GaN grown on sapphire to exploit the CTE mismatch between GaN and sapphire to reduce the bow during the cooling of the substrate prior to deposition of critical layers such as InGaN quantum well structures (Belousov, 2004). The optimization of this process can be sensitively dependent upon the growth parameters, layer thicknesses, and the mechanical properties of the substrate, and can be difficult to control reproducibly in a multi-wafer manufacturing process. Moreover this procedure is not effective for the case of growth on a substrate having a CTE which is smaller than the CTE of GaN, such as SiC or Si. Accordingly, a laminate substrate comprising a crystalline template layer attached to a substantially CTE-matched support substrate can be advantageously used as a replacement for a conventional CTE-mismatched bulk substrate. In this case the incremental stresses associated with heating or cooling of the substrate during the growth process are substantially reduced or eliminated. Therefore when a CTE-matched laminate substrate is used, it can be advantageous to employ such techniques as are known in the art to reduce or eliminate the initial tensile stress associated with the growth of the high temperature GaN. Such techniques include but are not limited to: (1) in-situ deposition of a silicon nitride masking layer using silane (or disilane) and ammonia precursors (Dadgar, 2003), preferably with a thickness between 1 monolayer and 3 monolayers, between the laminate film and the buffer or device layer, (2) optimization of the low-temperature AlN or GaN buffer layer thickness (Raghavan, 2005), preferably to a thickness between 4 nm and 10 nm, (3) inclusion within the high-temperature GaN buffer layer of between 1 and 7 AlN interlayers of between 10 nm and 100 nm thickness, where the AlN growth temperature is between 900 C and 1100 C and the spacing between the AlN interlayers is between 50 nm and 500 nm, to introduce compressive strain in the film (Schulze, 2006), (4) use of an indium precursor, such as trimethyl indium, to reduce the strain during the high-temperature GaN layer growth (Yamaguchi, 2000), (5) use of an Al-rich AlN buffer layer to promote compressive strain in the overgrown high-temperature GaN layer (Lu, 2004), or (6) use of a compliant interlayer, such as GaN(1−y)P(y), preferably with y<2% and a thickness between 20 nm and 60 nm, to reduce strain in the high-temperature GaN layer (Tsuda, 2005).

In the case of growth using a laminate substrate that includes a reflective support substrate such as an alloy of Mo or Mo—W, that is used to replace a transparent bulk substrate, such as sapphire or SiC, additional changes to the growth process can be made to advantage. For example the heater power required to maintain the required growth temperature can be adjusted in order to account for the difference in emissivity of the reflective laminate substrate compared to a transparent substrate. If the substrate is heated by means of RF induction, the heater power required to heat the laminate substrate can be substantially less compared to the transparent substrate, owing to the greater magnetic susceptibility of the laminate substrate material. Accordingly the heater power will preferably be lowered up to 50% depending on the composition of the support substrate material and the geometry of the RF heater. If the substrate is heated by a resistive heater, the resistive heater power may also be lowered. Thus, the resistive or RF induction heater power may be adjusted, such as lowered, during the epitaxial layer growth to account for a reflectivity and/or magnetic susceptibility of the support substrate.

Additionally the reflective properties of the laminate substrate enable the use of optical in-situ temperature measurement techniques as are known in the art such as pyrometry and emissivity-corrected pyrometry. In-situ optical detection of wafer curvature can also be employed. The availability of such in situ measurement techniques for growth on reflective laminate substrates containing an optically transparent laminate film can be exploited to fine-tune growth processes and maintain process control.

Various embodiments of a semiconductor devices and methods of making thereof are described herein. It should be noted that each embodiment can be used independently of the other embodiments or together with any one or more other embodiments described above. Thus a device or method may comprise any combination of one to all of the above described embodiments.

Although the foregoing refers to particular preferred embodiments, it will be understood that the present invention is not so limited. It will occur to those of ordinary skill in the art that various modifications may be made to the disclosed embodiments and that such modifications are intended to be within the scope of the present invention. All of the publications, patent applications and patents cited herein are incorporated herein by reference in their entirety.

References which are incorporated herein by reference in their entirety:
Belousov et al, J. Crystal Growth 272 (2004) 94
Chang et al, J. Crystal Growth 227 (2001) 214
Dadgar et al, Applied Physics Letters 82 (2003) 28
Einfeldt et al, Applied Physics Letters 80 (2002) 953
Frank et al, J. Crystal Growth 248 (2003) 421
Grzegorczyk et al, J. Crystal Growth 283 (2005) 72
Hsuch, J. Crystal Growth 258 (2003) 302
Lavoie et al, Canadian J. Physics 74 (1996) S47
Lu et al, J. Applied Physics 96 (2004) 4982
Mochizuki et al, J. Crystal Growth 273 (2005) 464
Mullan et al, J. Crystal Growth 182 (1997) 266
Park et al, J. Crystal Growth 258 (2003) 26
Raghavan et al, Applied Physics Letters 86 (2005) 261907
Schulze et al, Applied Physics Letters 88 (2006) 121114
Shimizu et al, J. Crystal Growth 265 (2004) 99
Tsuda et al, Applied Physics Letters 87 (2005) 201916
Yamaguchi et al, Appl. Surf. Sci. 159 (2000) 414
Yamaguchi et al, Applied Physics Letters 56 (1990) 27
Zeng et al, J. Crystal Growth 227 (2001) 210
Zhang et al, J. Crystal Growth 268 (2004) 24
Zheleva et al, Phys. Stat. Sol. 176 (1999) 545.

1. A method of making a semiconductor device, comprising:
providing a laminate substrate made by bonding a II-VI or III-V semiconductor laminate film to a support substrate; and
annealing the laminate substrate in an overpressure of a respective group VI or group V element.

2. The method of claim 1, further comprising epitaxially growing a semiconductor buffer layer on the laminate film of the laminate substrate.

3. The method of claim 1, wherein the respective Group VI or Group V element is the same as a respective Group VI or V element in the II-VI or III-V laminate film.

4. The method of claim 1, wherein the overpressure comprises a respective Group VI and Group V compound.

5. The method of claim 1, wherein group V or group VI containing gases are transported to a growth chamber by means of a carrier gas, and the carrier gas flow rate during the annealing process is less than a flow rate during the subsequent growth of a device structure.

6. The method of claim 1, wherein the laminate film comprises GaN and the overpressure comprises ammonia gas or a mixture of ammonia and hydrogen gas or ammonia and nitrogen gas.

7. A method of making a semiconductor device, comprising:
providing a laminate substrate made by bonding a III-V laminate film to a support substrate; and
epitaxially growing a buffer layer on the laminate film while providing a mobile Group III element to the laminate substrate.

8. The method of claim 7, wherein the step of providing a mobile Group III element comprises providing indium or an indium-containing compound.

9. The method of claim 8, wherein the III-V laminate film comprises an In or Ga—Group V film.

10. The method of claim 8, wherein the buffer layer comprises an In, Al or Ga—Group V film or the buffer layer comprises a ternary or quaternary alloy of In, Al, and/or Ga and Group-V element or elements.

11. The method of claim 8, wherein the buffer layer comprises a ternary or quaternary alloy of one or more of (i) In, Al, or Ga, and (ii) Group-V element or elements.

12. The method of claim 8, wherein the III-V laminate film comprises GaN, the buffer layer comprises InGaN, InAlN, or InAlGaN, and the step of providing a mobile Group III element comprises providing indium or an indium-containing compound.

13. A method of making a semiconductor device, comprising:
providing a laminate substrate made by bonding a laminate film to a support substrate;
epitaxially growing a III-nitride layer on the laminate film, wherein support substrate CTE is substantially equal to III-nitride layer CTE while the laminate film CTE is not equal to the III-nitride layer CTE; and
performing at least one of the following steps:
(1) in-situ deposition of a silicon nitride masking layer using silane or disilane and ammonia precursors; (2) growth of a low-temperature AlN or GaN buffer layer having an optimized thickness; (3) inclusion of a plurality of AlN interlayers of thickness between 10 nm and 200 nm within the GaN buffer layer to introduce compressive strain into the film; (4) use of an indium precursor to reduce strain during III-nitride layer growth; (5) use of an Al-rich AlN buffer layer to promote compressive strain in an overgrown high-temperature III-nitride layer, or (6) use of a compliant interlayer comprising GaN(1−y)P(y) where y<2%, having a thickness between 20 nm and 60 nm.
